(19) United States
(12) Patent Application Publication
(10) Pub. No.: US 2007/0085085 A1
(43) Pub. Date: Apr. 19, 2007

(54) Dissipative pick and place tools for light wire and LED displays

(76) Inventor: Steven F. Reiber, Rocklin, CA (US)

Correspondence Address: CARR & FERRELL LLP, 2200 GENG ROAD, PALO ALTO, CA, 94303, US

(21) Appl. No.: 11/463,285

(22) Filed: Aug. 8, 2006

Related U.S. Application Data
(60) Provisional application No. 60/730,613, filed on Oct. 26, 2005.
(60) Provisional application No. 60/706,632, filed on Aug. 8, 2005.

(51) Int. Cl. H01L 33/00

(52) U.S. Cl. 257/79

(57) ABSTRACT

The present invention provides for placement of an LED device on a carrier through the use of a pick-and-place tool. The tool conducts electricity at a rate sufficient to prevent charge buildup but not at so high a rate as to overload the LED being placed.

### CROSS REFERENCE TO RELATED APPLICATIONS

The present application claims the priority benefit of U.S. provisional patent application No. 60/730,613 (3455PRV) filed Oct. 26, 2005 and entitled “Dissipative Pick and Place Tools for Light Wire and LED Displays” and also claims the priority of U.S. provisional patent application No. 60/706,632 (3372PRV) filed Aug. 8, 2005 and entitled “Light Wire Manufacture”; this application also claims the priority benefit of U.S. patent application Ser. No. 11/227,982 (2834US) filed Sep. 14, 2005 and entitled “Multi-Head TAB Bonding Tool,” which claims the priority benefit of U.S. provisional patent application No. 60/610,847 (2834PRV) filed Sep. 17, 2004 and entitled “Multi-Head TAB Bonding Tool”; U.S. patent application Ser. No. 11/227,982 is also a continuation-in-part and claims the priority benefit of U.S. patent application Ser. No. 11/107,308 (3100US) filed Apr. 15, 2005 and entitled “Flip Chip Bonding Tool and Ball Placement Capillary,” which is a continuation-in-part and claims the priority benefit of U.S. patent application Ser. No. 10/942,311 (2617US) filed Sep. 15, 2004 and entitled “Flip Chip Bonding Tool Tip”; U.S. patent application Ser. No. 11/107,308 (3100US) is also a continuation-in-part and claims the priority benefit of U.S. patent application Ser. No. 10/943,151 (2835US) filed Sep. 15, 2004 and entitled “Bonding Tool with Resistance” and now U.S. Pat. No. 7,032,802; U.S. patent application Ser. Nos. 10/942,311 (2617US) and 10/943,151 (2835US) are both continuations-in-part and claim the priority benefit of U.S. patent application Ser. No. 10/650,169 (2615US) filed Aug. 27, 2003 entitled “Dissipative Ceramic Bonding Tool Tip” and now U.S. Pat. No. 6,935,548, which is a continuation of and claims the priority benefit of U.S. patent application Ser. No. 10/036,579 (1665US) filed Dec. 31, 2001, now U.S. Pat. No. 6,651,864, entitled “Dissipative Ceramic Bonding Tool Tip,” which claims the priority benefit of U.S. provisional patent application No. 60/288,203 (1665PRV) filed May 1, 2001; U.S. patent application Ser. No. 10/036,579 (1665US) is a continuation-in-part and claims the priority benefit of U.S. patent application Ser. No. 09/514,454 (1118US) filed Feb. 25, 2000, now U.S. Pat. No. 6,354,479 and entitled “Dissipative Ceramic Bonding Tool Tip,” which claims the priority benefit of provisional patent application No. 60/121,694 (1118PRV) filed Feb. 25, 1999; U.S. patent application Ser. No. 10/942,311 (2617US) also claims the priority benefit of U.S. provisional patent application No. 60/503,267 (2617PRV) filed Sep. 15, 2003 and entitled “Bonding Tool.” The disclosure of all of these applications is incorporated herein by reference.

### BACKGROUND OF THE INVENTION

1. Field of the Invention

This application relates to the manufacture of light wire or light rope, which may include various Light Emitting Diode (LED) displays, LED displays, LED numeric displays, and chip carriers. More specifically, the present invention relates to dissipative pick-and-place tools, tool tips, and die collets that may come in contact with and transfer a die from a wafer to an LED light wire or to an LED display or chip carrier or that place LEDs in light wires or light rope pockets and methods of manufacturing LEDs in long strips and large panels using ultrasonic bonding to embed a wire into a substrate.

2. Description of the Related Art

A prior method of making a light wire or rope was to use small light bulbs attached to a wire powered by AC and/or DC power. Despite being small, these bulbs occupied a great deal of space. Further, light bulbs were often too fragile for some settings (e.g., airplanes and cruise ships) and/or methods of manufacture.

LEDs are smaller and more durable semiconductor devices that emit incoherent narrow-spectrum light when electrically biased in the forward direction; this effect is a form of electroluminescence. Depending on the chemical composition of the semi-conducting material used in an LED, the color of the emitted light can be near-ultraviolet, visible, or infrared. LEDs have allowed for the creation of more manageable and durable light wire and light rope.

Notwithstanding the increased manageability and durability offered by the LED, other difficulties still exist with respect to light rope and light wire manufacture. For example, some light wires are made with a chip carrier that has a pocket. The aforementioned LED is placed in the pocket, which has small tabs that are bonded to the LED. These chip carriers are then attached to a wire. These chip carriers are generally very expensive and are also difficult to work with not only because they are large and inflexible but also because a large number of small LEDs must be very accurately placed in a very small space and subsequently bonded. All of this must occur at a high throughout rate depending on particular manufacture demands of a light wire or light rope manufacturer.

Pick-and-place tools have been used to help overcome some of the aforementioned difficulties. Pick-and-place tools allow for the pick up of a part (e.g., an LED), movement of the part to a desired locale and release of the part at that locale. A bonding operation may then take place with respect to the ‘placed’ part. For example, some chip carriers are made of metal with the LED glued to the metal and the power wire bonded to a gold pad. A small ball bonded wire is use to attach the LED to the power wire.

Pick-and-place tools in the prior art, however, are typically constructed of alumina (Al₂O₃). While offering a reasonably long operational life-span, prior art pick-and-place tool construction generally requires that no conductive binders be used. As a result, there is a risk of electrostatic discharge (ESD) from the pick-and-place tool making contact with the bonding pad of the desired circuit, which can damage the circuit. As LEDs use very small current to cause the emission of light, there is a need in the art for a dissipative pick-and-place tool or die collets that avoid the risk of ESD.

### SUMMARY OF THE INVENTION

An exemplary embodiment of the present invention discloses a method for placement of LEDs. Through this exemplary method, holes are cut in a light wire strip for the acceptance of an LED device. An LED device is placed in each of these holes and a current wire is embedded in the light strip. The current wire is then ultrasonically bonded to the LED device. The placement and/or bonding operation utilizes a tool, a portion of which is configured to conduct electricity at a rate sufficient to prevent charge buildup and further configured to conduct electricity at a rate that prevents an overload of the LED device.

In another exemplary embodiment of the present invention, a system for the placement of LEDs is disclosed. The system includes an automated device comprising a manipulator. The manipulator is fitted with an adaptor for accepting one or more tools. The tool is configured to be mechanically coupled to the manipulator and a portion of that tool conducts electricity at a rate sufficient to prevent charge build up but not so high a rate as to overload, for example, an LED being placed or bonded. The placement system may further include a tool magazine comprising a variety of different tools, including a pick-and-place tool or die collets. A computer program at a computing device may cause the automated device to retrieve a particular tool from the tool magazine, the particular tool being associated with a particular placement procedure. The computer program may further control the movement of the automated device with respect to a particular placement task. The computer program may be embodied on an optical or magnetic disk or in, for example, flash memory.

In another embodiment of the present invention, a pick-and-place tool for use in LED placement is disclosed. The tip of this exemplary pick-and-place tool includes a tip configured to conduct electricity at a rate sufficient to prevent charge build up but not so high a rate as to overload an LED being placed. In one exemplary embodiment, a resistance in the tip ranges from 10² to 10¹² ohms. In another embodiment, conduction in the tip is greater than one ten-billionth of a mho and less than one one-hundred thousandth of a mho.

The aforementioned pick-and-place tool tip may be, in various embodiments, inclusive of ceramics. This ceramic may be electrically non-conductive. The aforementioned pick-and-place tools may be, in other embodiments, inclusive of carbide. The aforementioned carbide may be electrically conductive.

In some embodiments, the tip is constructed of (in whole or in part) a uniform extrinsic semi-conducting material having dopant atoms in a concentration and valence state to produce a sufficient mobile charge carrier density that results in electrical conduction within a predetermined range; this embodiment may include a tip composed of a polycrystalline silicon carbide uniformly doped with boron.

In another embodiment, the tip is constructed of (in whole or in part) a thin layer of a highly doped semiconductor on an insulating core, the tip having mechanical stiffness, abrasion resistance, and further providing a charge carrier path that permits dissipation of electrostatic charge at a predetermined rate. Such a tip may include a diamond tip wedge that is ion implanted with boron. Alternatively, the tip may include a diamond tip wedge that is ion implanted with a doped ceramic.

In a still further embodiment of the pick-and-place tool tip, the tip may be constructed of (in whole or in part) a lightly doped semiconductor layer on a conducting core, the tip having mechanical stiffness, abrasion resistance, and electrical conduction that permits dissipation of an electrostatic charge at a predetermined rate. This particular tip may be cobalt bonded tungsten carbide coated with titanium nitride carbide.

The pick-and-place tool tip may be constructed in a variety of fashions. In one embodiment, the tip may be manufactured through the mixing, molding and sintering reactive powders. In another embodiment, the tip may be manufactured through the use of hot pressing reactive powders. In yet another embodiment, the tip may be manufactured through fusion casting.

### BRIEF DESCRIPTION OF THE DRAWINGS

FIG. 1 illustrates a series of exemplary die collets, which may be used in the practice of various embodiments of the present invention with respect to conducting electricity at a rate sufficient to prevent charge buildup and also at a rate that prevents an overload of a device in contact or physical proximity of the die collets.

FIG. 2 illustrates a series of exemplary vacuum pick up tools, which may be used in the practice of various embodiments of the present invention with respect to conducting electricity at a rate sufficient to prevent charge buildup and also at a rate that prevents an overload of a device in contact or physical proximity of the pick up tools.

FIGS. 3a, 3b, and 3c illustrate an exemplary two-layered structure of a tool tip as may be implemented in various embodiments of the present invention with respect to conducting electricity at a rate sufficient to prevent charge buildup and also at a rate that prevents an overload of a device in contact or physical proximity of the tip.

FIG. 4 illustrates an exemplary method of manufacture with respect to the use of mixing, molding and sintering reactive powders

FIG. 5 illustrates an exemplary method of manufacture through the use of hot pressing reactive powders.

FIG. 6 illustrates an exemplary method of manufacture through fusion casting.

FIG. 7 illustrates a section of an exemplary numeric keypad display as may be subject to various pick-and-place and/or bonding operations utilizing an embodiment of the presently disclosed invention.

FIG. 8a illustrates an exemplary RFID carrier as may be subject to various pick-and-place and/or bonding operations utilizing an embodiment of the presently disclosed invention.

FIG. 8b is a cross-section of an exemplary RFID chip carrier.

FIG. 9 illustrates an exemplary light wire comprising a conductive adhesive to make contact between the ground on the LEDs and the main ground wires and as may be subject to various pick-and-place and/or bonding operations utilizing an embodiment of the presently disclosed invention.

FIG. 10 illustrates an exemplary light wire with a small ground wire that makes contact with the large ground wire between every LED and as may be subject to various pick-and-place and/or bonding operations utilizing an embodiment of the presently disclosed invention.

FIG. 11 illustrates a cross-section of an exemplary light wire with a small ground wire.

FIG. 12 illustrates an exemplary LED panel display that may be of various sizes or design configurations (e.g., shapes) and as may be subject to various pick-and-place and/or bonding operations utilizing an embodiment of the presently disclosed invention.

FIG. 13 illustrates a cross-section of an exemplary light wire using a large ground line and conductive adhesive to make contact with an LED and as may be subject to various pick-and-place and/or bonding operations utilizing an embodiment of the presently disclosed invention.

FIG. 14 illustrates a cross-section of an exemplary panel with LED contacts on both sides of the panel and as may be subject to various pick-and-place and/or bonding operations utilizing an embodiment of the presently disclosed invention.

### DETAILED DESCRIPTION

Various embodiments of the present invention allow for an LED to be picked up from a wafer and placed on a carrier with a pick-and-place tool or machine. The part of the tool that comes in contact with the LED is, in an embodiment, made with a conductive or insulative material that conducts electricity at a rate sufficient to prevent charge buildup but not at so high a rate as to overload the LED.

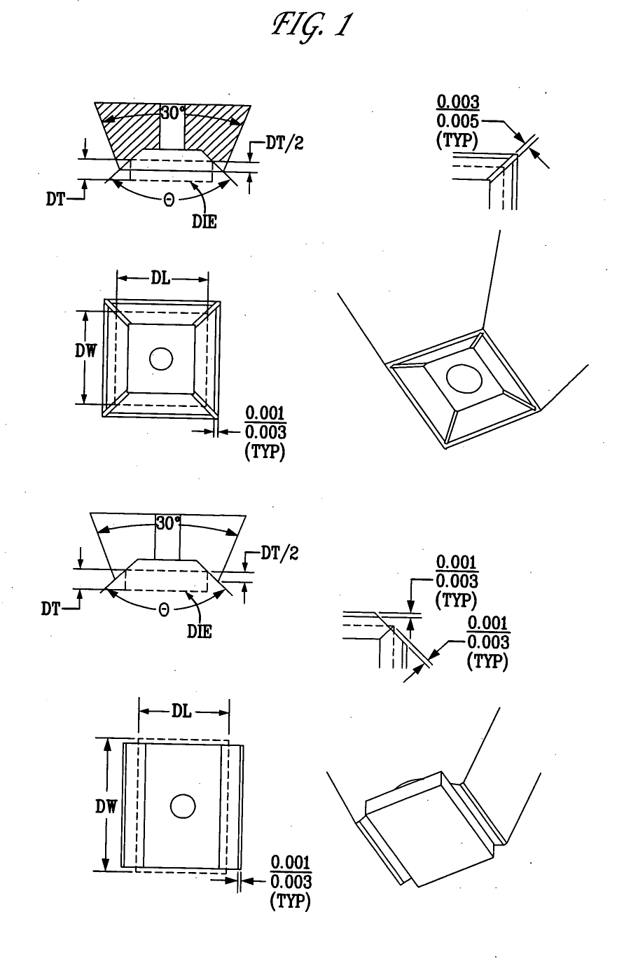

FIG. 1 illustrates a series of exemplary die collets, which may be used in various embodiments of the present invention with respect to conducting electricity at a rate sufficient to prevent charge buildup and also at a rate that prevents an overload of a device in contact or physical proximity of the die collets. Die collets may be used to attach, for example, a die to a substrate. The inside of die collets, in exemplary embodiments, may have slants sides (for example, 90 degrees) but may be modified to various slant configurations depending upon the needs of the particular tool or job.

Four-sided collets are generally referred to as having an ‘inverted pyramid’ design whereas two-sided collets are generally referred to as having a ‘channel’ design. Four-sided (inverted pyramid) collets may be advantageous in some jobs in that the die collets offer greater control of the positioning of a die because the die is contained on all four sides. Alternatively, two-sided (channel) die collets may be advantageous in some jobs in that they offer additional clearance on each end used to place a die adjacent to, for example, a device.

Die collets may be manufactured such that various percentages of die thickness are engaged and exposed. In some embodiments, thinner die sizes than what are actually being used may be implemented. In these embodiments, eutectic or epoxy material may be prevented from extruding onto the face of the die collets.

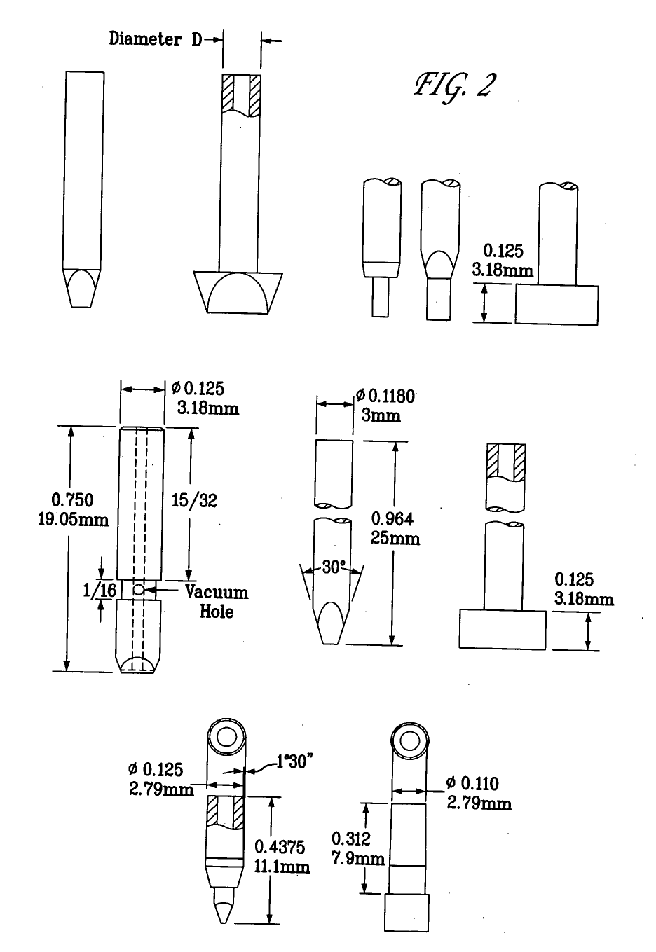

FIG. 2 illustrates a series of exemplary vacuum pick up tools, which may be used in the practice of various embodiments of the present invention with respect to conducting electricity at a rate sufficient to prevent charge buildup and also at a rate that prevents an overload of a device in contact or physical proximity of the pick up tools. A flat-faced vacuum pick-up tool may be used to hold a die against the face of the tool allowing for use of the tool in die attachment. This process has traditionally been implemented in the context of, for example, epoxy die attachment operations but may also be used in the case of, for example, eutectic bonding on smaller die sizes.

In various embodiments of the present invention, a thin strip of, for example, polymer of vinyl chloride (PVC) or other material may be provided. Small holes may be cut out in the strip for placement of an LED device(s). Following placement of the LED device(s), wires may be ultrasonically embedded in the plastic. For example, in a configuration utilizing eight ultrasonically embedded wires, two of the wires may be small enough (e.g., 0.001 to 0.002 mm) so that light emitted from the LED is not blocked or otherwise obscured. Six larger wires (e.g., 0.004 to 0.070 mm) may carry the current to the LED device(s). The size of the wire may vary to the length of the light wire.

In one exemplary embodiment of LED placement, there may be resistors every 6 to 15 inches that bridge a large power wire to a small LED wire and small shunt wires every 6 to 24 inches to a large ground wire. The small wire may be ultrasonically bonded or conductively adhered to the LED. A conformal coat may then be placed over the bonded area. In this exemplary configuration (and others within the scope and spirit of the presently described invention), the LEDs may use very small current to cause the emission of light, which calls for the use of a dissipative pick-and-place tool or die collets with little to no electrical charge stored on the tool as to avoid ESD.

Pick-and-place tools in the prior are typically constructed of alumina (Al₂O₃), sometimes termed aluminum oxide, or tungsten carbide. These compounds are generally very hard, which offers a benefit of reasonably long life in a commercial or industrial setting. To ensure that the tool is an insulator, no conductive binders are used with such prior art pick-and-place tools. As a result, however, an electrical charge may build-up and an electrostatic discharge from the pick-and-place tool making contact with, for example; a bonding pad or the LED may occur, which may damage the circuit. Such detrimental operations are overcome by the presently disclosed pick-and-place tool, which conducts electricity at a rate sufficient to prevent charge buildup but not at so high a rate as to overload the device being bonded.

In such an embodiment, an exemplary pick-and-place tool may have electrical conduction greater than one ten-billionth of a mho (i.e., >1×10⁻¹² reciprocal ohms) but less than one one-hundred thousandth of a mho (i.e., <1×10⁻² reciprocal ohms). The resistance, in an exemplary embodiment, should be low enough so that the material is not an insulator but high enough so that the tool does not become a conductor and allow for a current flow. A resistance in the tip assembly, in one embodiment, may range from 10² to 10¹² ohms. For example, in one embodiment, no more than 2 to 3 milliamps of current should be allowed to pass through the tip of a pick-and-place tool to a device being bonded.

Such a pick-and-place tool may have specific mechanical properties with respect to particular jobs (i.e., a particular situation in which the tool is being utilized). These properties may include high stiffness and high abrasion resistance. Such properties may suggest the use of ceramics (e.g., electrical non-conductors) or metals such as tungsten carbide (e.g., electrical conductors). Other properties may include a particular hardness. For example, the top of a tool may have a Rockwell hardness that ranges from 55 to 365 or higher. The tool may also be designed with duration of operation in mind. For example, a tool may be required to last for a particular number of bonding operations before replacement or, similarly, for a particular number of bonding operations prior to cleaning. Various factors may be considered with respect to the design and configuration of a particular pick-and-place tool (or other tools for that matter) such as increasing the number of units per hour bonded or general manufacture throughput.

In one embodiment of the present invention, a pick-and-place tool tip may be constructed from a uniform extrinsic semi-conducting material that has dopant atoms in an appropriate concentration and valence states to produce sufficient mobile charge carrier densities (unbound electrons or holes). Variances in the concentration and valence state will allow for electrical conduction within a desired and predetermined range. An example of such a construction is a polycrystalline silicon carbide uniformly doped with boron.

In another embodiment of the present invention, a pick-and-place tool tip may be constructed by forming a thin layer of a highly doped semiconductor on an insulating core. In such an embodiment, the core may provide the mechanical stiffness and the semiconductor surface layer may provide abrasion resistance and a charge carrier path from the tool tip to the tool mount. This carrier path may then permit dissipation of electrostatic charge at an acceptable and/or otherwise predetermined rate subject to, for example, various concentrations of tool construction materials. An example of such a construction is a diamond tip wedge that has a surface ion implanted with boron or a doped ceramic.

In yet another embodiment, the pick-and-place tool tip may be formed through the use of a lightly doped semiconductor layer on a conducting core. The conducting core may provide the requisite mechanical stiffness. The semiconductor layer, in turn, may provide abrasion resistance and a charge carrier path from the tool tip to conducting core, which is electrically connected to the tool mount. The doping level may be chosen to produce conductivity through the layer, which will then permit dissipation of electrostatic charge at an acceptable and otherwise predetermined rate. An example of such a construction includes cobalt bonded tungsten carbide coated with titanium nitride carbide.

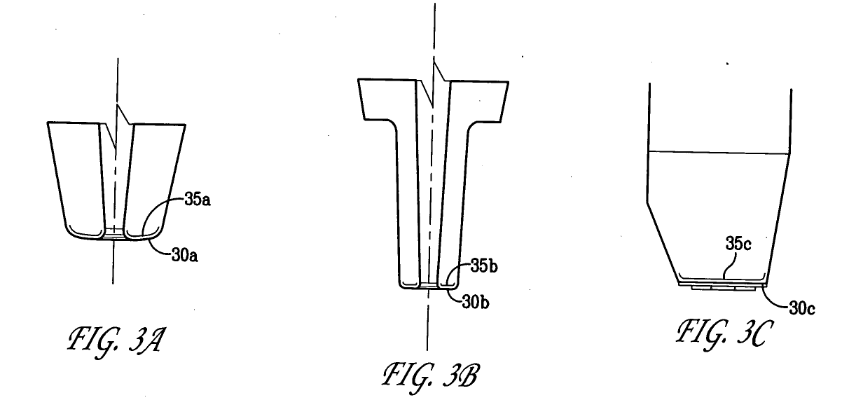

FIGS. 3a, 3b, and 3c illustrate an exemplary two-layered structure of a tool tip as described above and as may be implemented in the context of a pick-and-place and/or bonding tool as claimed herein. This exemplary structure in FIGS. 3a, 3b, and 3c is not intended to be limiting but rather an exemplary configuration for the purposes of better understanding the presently described and claimed invention. The outer layers are labeled 30a, 30b, and 30c, respectively, and the cores are labeled 35a, 35b, and 35c. No significance should be attached to the relative thickness or scale of the portions of the outer layers in the present figures as such a layer may or may not have a uniform thickness.

Dissipative pick-and-place tools may be manufactured through the use of mixing, molding and sintering reactive powders. Such tool may also be manufactured through the use of hot pressing reactive powders. Dissipative pick-and-place tools may also be manufactured through fusion casting.

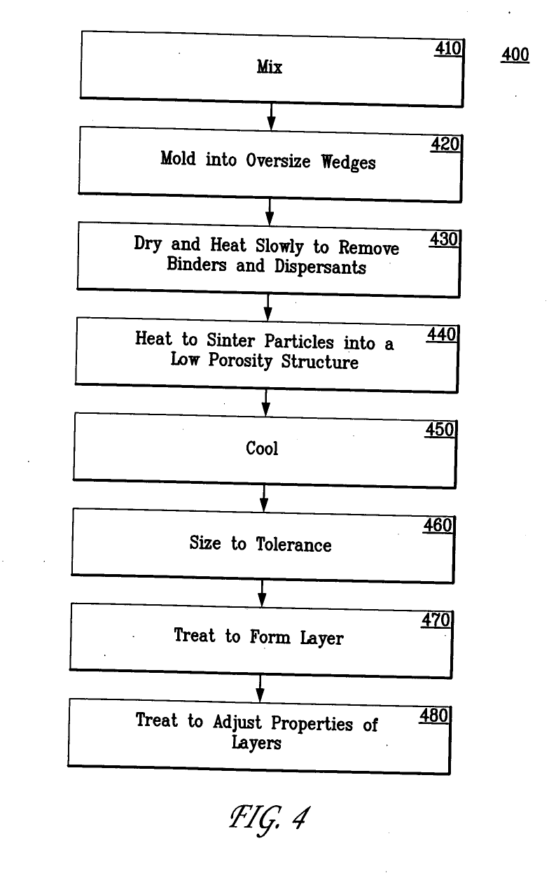

FIG. 4 illustrates a method of manufacture 400 with respect to the use of mixing, molding and sintering reactive powders. In step 410, fine particles of a desired composition may be mixed with organic and inorganic solvents, dispersants, binders and sintering aids and then molded into oversized wedges in step 420. In step 430, the wedges are carefully dried and slowly heated to remove the binders and dispersants. In step 440, the wedges are then heated to a high enough temperature so that the individual particles sinter together into a solid structure with low porosity. The heat-treating atmosphere may be chosen to facilitate the removal of the binder at a low temperature and to control the valence of the dopant atoms at the higher temperature and while cooling (step 450).

After cooling in step 450, the wedges may optionally be machined to achieve required tolerances in step 460. The wedges may then further optionally be treated in step 470 to produce a desired surface layer by ion implementation, vapor deposition, chemical vapor deposition, physical deposition, electroplating deposition, neutron bombardment or combinations of the above. In optional step 480, the pieces may be subsequently heat treated in a controlled atmosphere to produce the desired layer properties through diffusion, re-crystallization, dopant activation or valence changes of metallic ions.

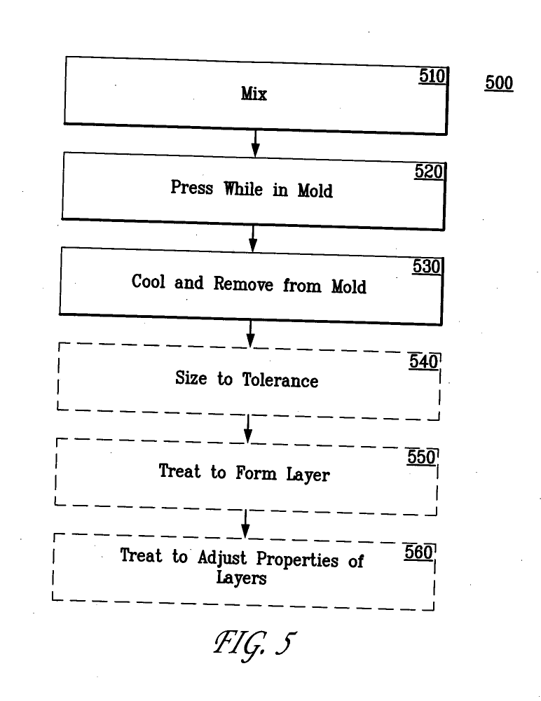

FIG. 5 illustrates a method of manufacture 500 through the use of hot pressing reactive powders. In step 510, fine particles of a desired composition may be mixed with binders and sintering aids and then pressed (in step 520) in a mold at a high enough temperature to cause consolidation and binding of the individual particles into a solid structure with low porosity. The hot pressing atmosphere may be chosen to control the valence of the dopant atoms. The pieces are cooled and removed from the hot press in step 530.

The pieces may then optionally be machined to achieve required tolerances at step 540. The pieces may optionally be treated (in step 550) to produce a desired surface layer by ion implantation, vapor deposition, chemical vapor deposition, physical deposition, electroplating deposition, neutron bombardment or combinations of the above. The pieces may subsequently be heat treated in optional step 560 in a controlled atmosphere to produce desired layer properties through diffusion, re-crystallization, dopant activation or valence changes of metallic ions.

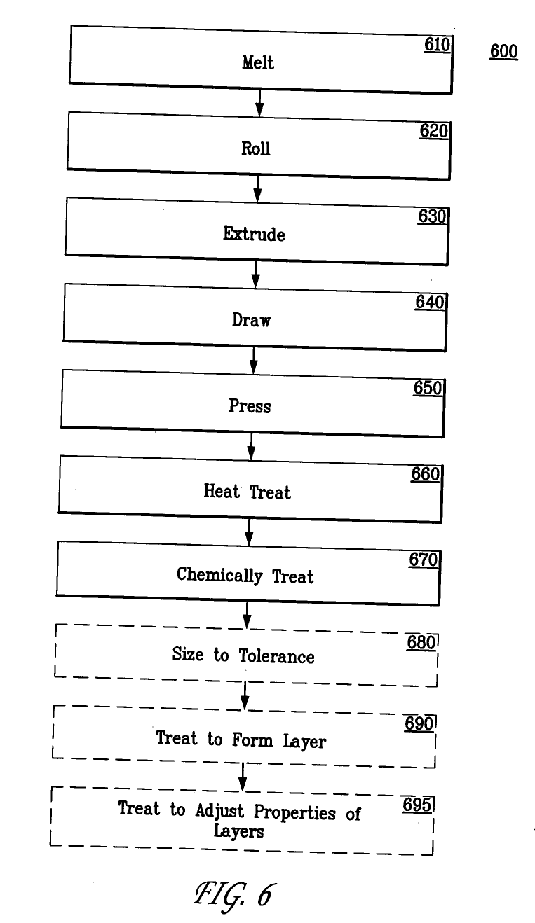

A method of manufacture 600 through fusion casting is disclosed in FIG. 6. In step 610, metals of a desired composition are melted in a non-reactive crucible; then cast into an ingot. The ingot is then rolled (step 620), extruded (step 630), drawn (step 640), pressed (step 650), heat-treated in a suitable atmosphere in step 660 and chemically treated in step 670.

The pieces may then be machined to achieve required tolerances in optional step 680. In optional step 690, the metallic pieces may also be heat-treated to produce a desired surface layer by vapor deposition, chemical vapor deposition, physical deposition, electroplating deposition or combinations of the above. The pieces may subsequently be heat-treated in a controlled atmosphere to produce desired layer properties through diffusion, re-crystallization, dopant activation or valence changes of metallic ions in optional step 695.

The layer used in the bonding process may be a dissipated ceramic comprising alumina (aluminum oxide Al₂O₃) and zirconia (zirconium oxide ZrO₂) and other elements. This mixture is both somewhat electrically conductive and mechanically durable. The tip of a pick-and-place tool may be coated with this material or it may be made completely out of this material. In such an embodiment, the range of alumina may extend from 15% to 85% and the range of zirconia from 15% to 85%. Another embodiment may include a concentration of alumina at 40% and zirconia at 60%. Another bonding layer composition may include a combination of iron; oxygen; sodium; carbon; zirconium; silicon; aluminum; yttrium.

Such a pick-and-place too may be utilized in any variety of automated devices. For example, such devices may include robots or other numerically controlled machines. These various devices may include a manipulator, such as an arm, a spindle, or any other movable structure, whose movement is controlled by a computer. To increase the functionality of the automated device, the manipulator may be fitted with an adapter for accepting different tools. Each of the different tools may allow the manipulator to perform a different function or job. The adapter may accept, for example, machining tools, grasping tools, welding tools, as well as the presently described pick-and-place tool. These different tools may be stored in a tool magazine.

The automated device may be programmed to retrieve the different tools from the tool magazine as the tools are needed to perform various procedures and jobs. The presently described pick-and-place tool may allow the manipulator to pick up a part, move the part to a desired location, and release the part at the desired location. One application of a pick-and-place tool is in automated machining, such as, for example, computer automated machining (CAM), computer numerical control (CNC) machining, or robotic machining in addition to LED placement.

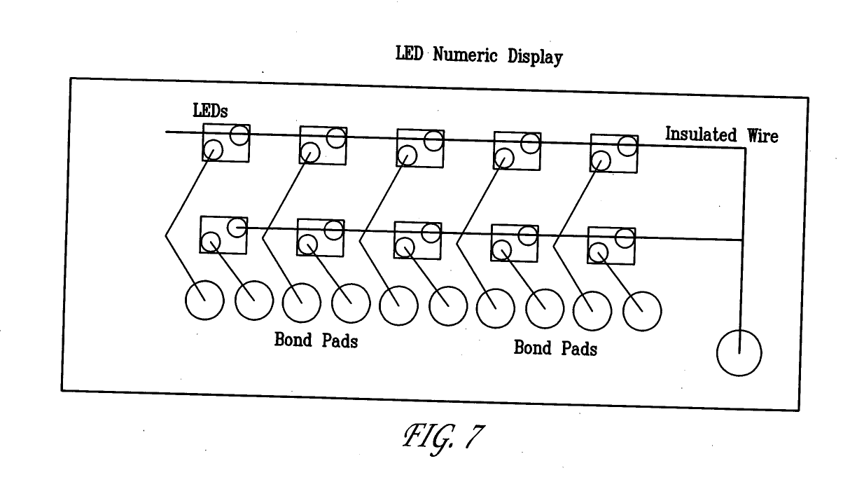

FIG. 7 illustrates a section of an exemplary numeric keypad display as may be subject to various pick-and-place and/or bonding operations utilizing an embodiment of the presently disclosed invention. The power wires in the exemplary display are bare wire and the ground is insulted wire to prevent the two-wire cross from shorting. Various other embodiments of wire configurations may be implemented depending on, for example, the nature of the particular device and the LED combination/configuration utilized in the same.

In the presently illustrated example, the LEDs may also be used in credit cards or other small devices. These LEDs ‘light up’ when a key is pressed on the device. Small power wires running down to bond pads may be bare or insulated wires and bonded to the pad with ultrasonic or conductive adhesive. A ground wire is insulted so that it can cross over or under the power wires and not short out. Various placement and/or bonding operations of the present keypad display may take place through the use of the various pick-and-place and/or bonding tools as described herein.

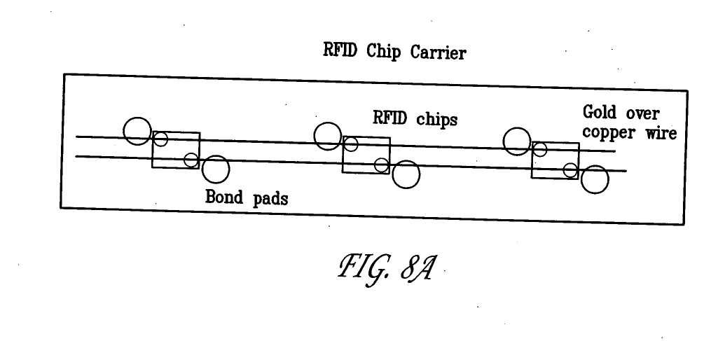

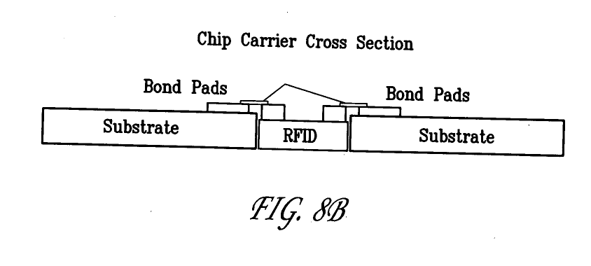

FIG. 8a illustrates an exemplary Radio Frequency Identification (RFID) carrier as may be subject to various pick-and-place and/or bonding operations utilizing an embodiment of the presently disclosed invention. The present example illustrates an RFID chip embedded into a substrate with bond pads on each side. A wire may make contact with the RFID and the bond pads. The bond pads may also have an antenna wire attached when the carrier is installed in an RFID device. Various placement and/or bonding operations may take place through the use of the various pick-and-place and/or bonding tools described herein. FIG. 8b is a cross-section of an exemplary RFID chip carrier.

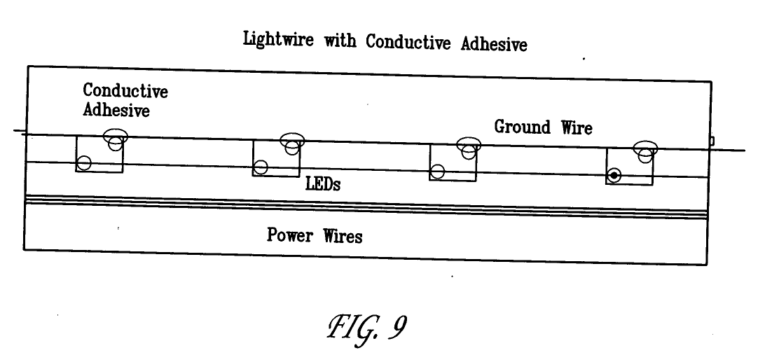

FIG. 9 illustrates an exemplary light wire comprising a conductive adhesive to make contact between the ground on the LEDs and the main ground wires and as may be subject to various pick-and-place and/or bonding operations utilizing an embodiment of the presently disclosed invention.

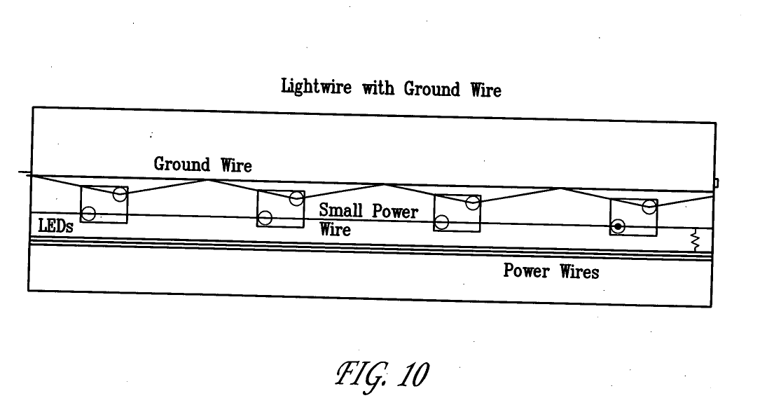

FIG. 10 illustrates an exemplary light wire with a small ground wire that makes contact with the large ground wire between every LED and as may be subject to various pick-and-place and/or bonding operations utilizing an embodiment of the presently disclosed invention. In the present example, eight 10 millimeter power wires running on a substrate with four on top of the substrate and four on the bottom are shown. Cut outs made every few inches from where conductive adhesive is place over the wires allows for operation as one conductor. Alternate embodiments may comprise any number of wires.

A small power wire may, in one embodiment, be constructed of gold, copper, or gold over copper. These wires may be ultrasonically bonded to a die and have a resistor placed every few LEDs. In this manner, 24 volts of DC may run through the large wire and, by using the resistor, step down the voltage to a level that the LED may use. Such an embodiment allows for the making of long strips of continuous LEDs. Various placement and/or bonding operations may take place through the use of the various pick-and-place and/or bonding tools described herein

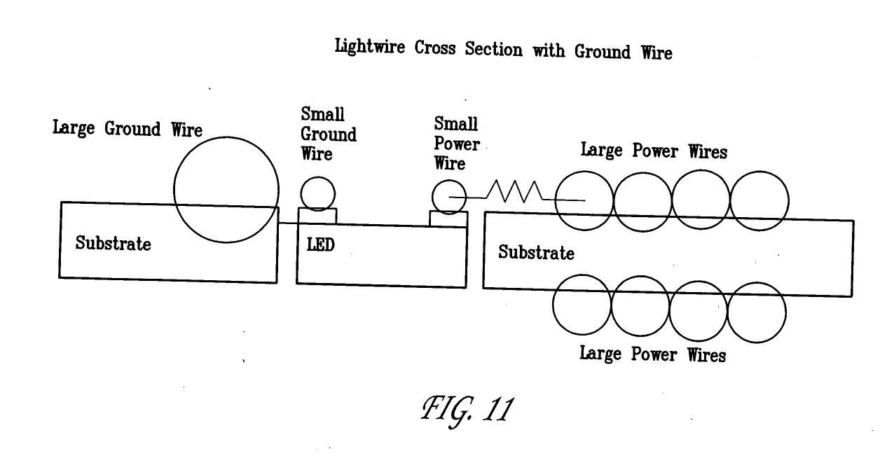

FIG. 11 illustrates an enlarged, cross-sectional view of an exemplary light wire or large LED display panel. The present figure illustrates how power wires and LEDs are on the same plane making the bonding of the wires to the LEDs and the substrate a single piece of material.

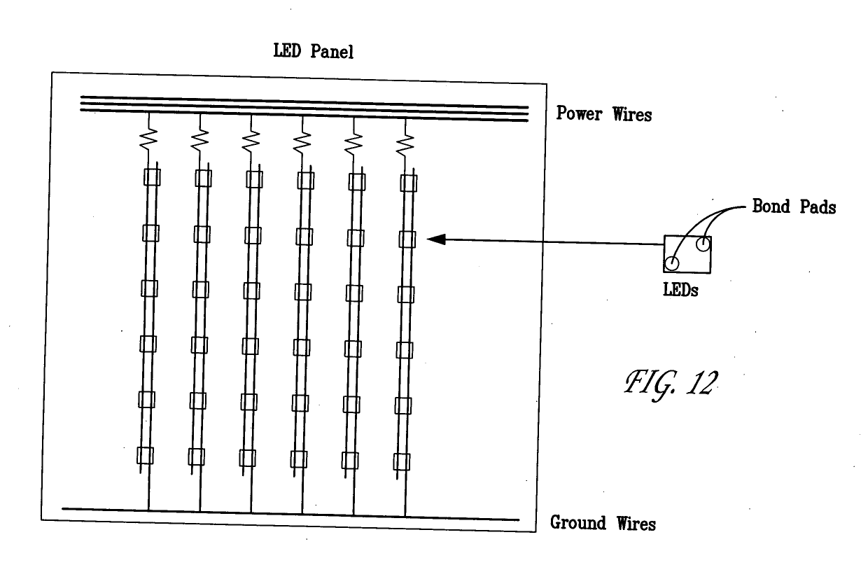

FIG. 12 illustrates an exemplary LED panel display that may be of various sizes or design configurations (e.g., shapes) and as may be subject to various pick-and-place and/or bonding operations utilizing an embodiment of the presently disclosed invention. The present figure illustrates a large LED display panel with power lines running the sides of the panel and small power wires running from the LEDs to the large power wires. Such a configuration may be implemented on a clear Mylar sheet such that one can see through the panel. Such configurations may be implemented in the shapes of letters or numbers. In an embodiment, an adhesive may be placed between the LED and the ground wire. Various placement and/or bonding operations may take place through the use of the various pick-and-place and/or bonding tools described herein.

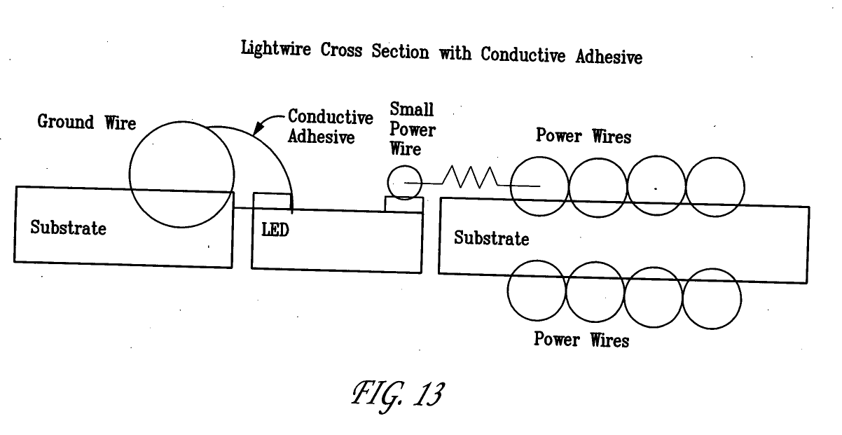

FIG. 13 illustrates a cross-section of an exemplary light wire using a large ground line and conductive adhesive to make contact with an LED and as may be subject to various pick-and-place and/or bonding operations utilizing an embodiment of the presently disclosed invention. In the present example, a substrate where a wire is bonded to a section or group of LEDs is disclosed. In such an embodiment, a group may comprise about 15 LEDs depending on the wire size and current need of the LED although any number of LEDs may be utilized. A resistor, in the presently described embodiment, may then placed at every group to drop the voltage to a level that is required and/or can be handled by the LED. A ground may include one or two large wires running along side the LEDs with conductive adhesive. Various placement and/or bonding operations may take place through the use of the various pick-and-place and/or bonding tools described herein.

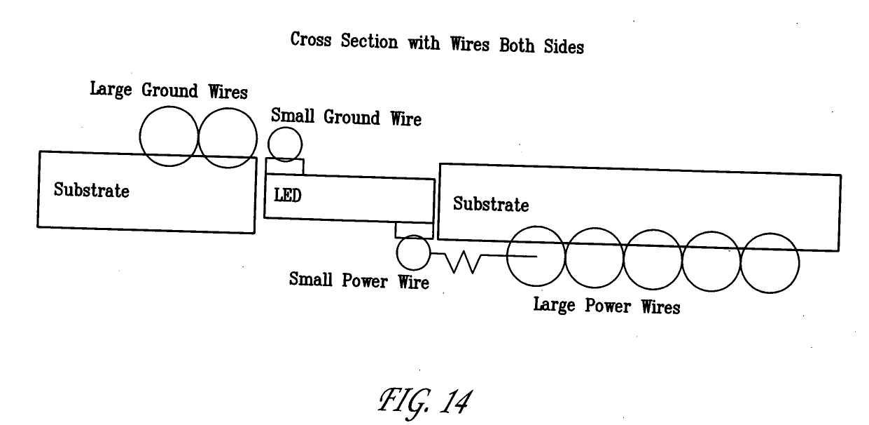

FIG. 14 illustrates a cross-section of an exemplary panel with LED contacts on both sides of the panel and as may be subject to various pick-and-place and/or bonding operations utilizing an embodiment of the presently disclosed invention. In the present example, an LED in a substrate where a wire is bonded to a section or group of LEDs and where a resistor is placed at every group to drop the voltage level to such a level that may be handled by the LED is disclosed. A ground is one or two large wires that run along side the LEDs with a small wire that runs in between the LEDs and makes contact with the large ground. Various placement and/or bonding operations may take place through the use of the various pick-and-place and/or bonding tools described herein.

While the invention has been described with reference to exemplary embodiments, it will be understood by those skilled in the art that various changes may be made and equivalents may be substituted for elements thereof without departing from the true spirit and scope of the invention. In addition, modifications may be made without departing from the essential teachings of the invention. For example, utilizing the various embodiments disclosed herein for the purpose of bonding tools, specifically with respect to LED devices.

What is claimed is:

1. A method for placement of Light Emitting Diodes (LEDs), comprising:
cutting a plurality holes in a light wire strip, the plurality of holes configured to accept an LED device;
placing an LED device in each of the plurality of holes;
embedding a current wire in the light strip; and
ultrasonically bonding the current wire to the LED device, wherein the current wire is bonded to the LED device utilizing a bonding tool at least a portion of which is configured to conduct electricity at a rate sufficient to prevent charge buildup and further configured to conduct electricity at a rate that prevents an overload of the LED device.

2. A system for the placement of Light Emitting Diode (LEDs), comprising:
an automated device comprising a manipulator, wherein the manipulator is fitted with an adaptor for accepting one or more tools; and
a tool configured to be mechanically coupled to the manipulator, wherein the tool comprises at least a portion configured to conduct electricity at a rate sufficient to prevent charge build up but not so high a rate as to overload an LED being placed.

3. The system of claim 2, further comprising a tool magazine comprising a plurality of tools.

4. The system of claim 3, further comprising a computing device programmed to cause the manipulator to retrieve a particular tool from the tool magazine, the particular tool being associated with a particular placement procedure.

5. The system of claim 3, further comprising a computing device programmed to control a movement of the manipulator with respect to a particular placement task.

6. The system of claim 2, wherein the tool is a pick-and-place tool.

7. The system of claim 2, wherein the tool is a bonding tool.

8. The system of claim 2, wherein the tool is a die collets.

9. A pick-and-place tool for use in LED placement, comprising a tip configured to conduct electricity at a rate sufficient to prevent charge build up but not so high a rate as to overload an LED being placed.

10. The pick-and-place tool of claim 9, wherein a resistance in the tip ranges from 10² to 10¹² ohms.

11. The pick-and-place tool of claim 9, wherein conduction in the tip is greater than one ten-billionth of a mho and less than one one-hundred thousandth of a mho.

12. The pick-and-place tool of claim 9, wherein the tip comprises a ceramic.

13. The pick-and-place tool of claim 12, wherein the ceramic is electrically non-conductive.

14. The pick-and-place tool of claim 9, wherein the tip comprises a carbide.

15. The pick-and-place tool of claim 14, wherein the carbide is electrically conductive.

16. The pick-and-place tool of claim 9, wherein the tip comprises a uniform extrinsic semi-conducting material having dopant atoms in a concentration and valence state to produce a sufficient mobile charge carrier density that results in electrical conduction within a predetermined range.

17. The pick-and-place tool of claim 16, wherein the tip comprises polycrystalline silicon carbide uniformly doped with boron.

18. The pick-and-place tool of claim 9, wherein the tip comprises a thin layer of a highly doped semiconductor on an insulating core, the tip having mechanical stiffness, abrasion resistance, and further providing a charge carrier path that permits dissipation of electrostatic charge at a predetermined rate.

19. The pick-and-place tool of claim 18, wherein the tip comprises a diamond tip wedge that is ion implanted with boron.

20. The pick-and-place tool of claim 18, wherein the tip comprises a diamond tip wedge that is ion implanted with a doped ceramic.

21. The pick-and-place tool of claim 9, wherein the tip comprises a lightly doped semiconductor layer on a conducting core, the tip having mechanical stiffness, abrasion resistance, and electrical conduction that permits dissipation of an electrostatic charge at a predetermined rate.

22. The pick-and-place tool of claim 21, wherein the tip comprises cobalt bonded tungsten carbide coated with titanium nitride carbide.

23. The pick-and-place tool of claim 9, wherein the tip is manufactured through the mixing, molding and sintering reactive powders.

24. The pick-and-place tool of claim 9, wherein the tip is manufactured through the use of hot pressing reactive powders.

25. The pick-and-place tool of claim 9, wherein the tip is manufactured through fusion casting.

26. A method for placement of Light Emitting Diodes (LEDs), comprising:
cutting a plurality holes in a light wire strip, the plurality of holes configured to accept an LED device;
placing an LED device in each of the plurality of holes, wherein the LED device is placed using a pick-and-place tool at least a portion of which is configured to conduct electricity at a rate sufficient to prevent charge buildup and further configured to conduct electricity at a rate that prevents an overload of the LED device;
embedding a current wire in the light strip; and
ultrasonically bonding the current wire to the LED device.
